(19) United States
(12) Patent Application Publication
(10) Pub. No.: US 2002/0009888 A1
(43) Pub. Date: Jan. 24, 2002

(54) Method of producing a semiconductor device

(75) Inventor: Akira Mizumura, Tokyo (JP)

Correspondence Address: SONNENSCHEIN NATH & ROSENTHAL, P.O. BOX 061080, WACKER DRIVE STATION, CHICAGO, IL, 60606-1080, US

(73) Assignee: Sony Corporation

(21) Appl. No.: 09/907,373

(22) Filed: Jul. 17, 2001

(30) Foreign Application Priority Data
Jul. 18, 2000 (JP) P2000-216974

(51) Int. Cl. H01L 21/311

(52) U.S. Cl. 438/694; 438/695

(57) ABSTRACT

There is provided a method of producing a semiconductor device in which TAT can be improved while withstand voltage of a damaged insulating film is secured. A TEOS film is formed to cover a gate wiring line on a substrate, and a side wall is formed on a wall of the gate wiring line through the TEOS film. After ion implantation is carried out from above the side wall, the side wall is removed by dry etching. Thereafter, the surface of the TEOS film is exposed to a film formation atmosphere of the TEOS film. By this, the damage given to the surface of the TEOS film by the dry etching for removing the side wall is restored. Then, the withstand voltage of the TEOS film is secured without forming a new film for reinforcement.

### BACKGROUND OF THE INVENTION

1. Field of Invention

The present invention relates to a method of producing a semiconductor device, and particularly to a method of producing a semiconductor device in which TAT (Turn Around Time) can be improved.

2. Related Art

In recent years, as the degree of integration of a semiconductor device rises at an increasing tempo, an average distance between respective layers is remarkably shortened, and it becomes difficult to secure withstand voltage between them.

In a production step of a semiconductor device, there is a case where the surface of an insulating film covering a conductive layer is exposed to dry etching. FIGS. 4A to 4D show part of a production process of a semiconductor device including such a step. In the production process shown in the drawings, first, as shown in FIG. 4A, an insulating film 3 having a thickness of about 30 nm is formed to cover a gate wiring line 2 formed on a substrate 1. Next, a polysilicon film is formed on an upper portion, and the polysilicon film is etch backed so that a side wall 4 made of polysilicon is formed on a wall of the gate wiring line 2 through the insulating film 3. Then, ion implantation for formation of source/drain regions (not shown) is carried out from above the side wall 4.

Thereafter, as shown in FIG. 4B, the side wall 4 on the insulating film 3 is selectively removed. At this time, the insulating film 3 as the under layer of the side wall 4 is exposed to an etching atmosphere and is damaged. Thus, the surface of the insulating film 3 becomes brittle, and pin holes are produced, so that the insulation property is lowered.

Then, as shown in FIG. 4C, an insulating film 6 made of a material identical to or different from the insulating film 3 is formed to a thickness of 10 nm to 50 nm, so that the damaged insulating film 4 is reinforced. Thereafter, as shown in FIG. 4D, an interlayer insulating film 7 is formed in a state where it is embedded in the roughness on the substrate 1, and the surface is flattened. Next, a connection hole 8 reaching the substrate 1 is formed in the interlayer insulating film 7 and the insulating films 3 and 6, and a conductive material is embedded in the connection hole 8 to form a plug 9.

According to such a production method, the damaged insulating film 4 is reinforced by the newly formed insulating film 6, and the withstand voltage between the plug 9 and the gate wiring line 2 is secured.

In recent years, as the function of a semiconductor device is highly advanced, the number of steps is remarkably increased in the production process of the semiconductor device, and there is a tendency that the TAT (Turn Around Time) is prolonged. And yet, in the foregoing production method, in order to reinforce the already formed insulating film 3, the insulating film 6 is newly formed. This becomes a factor lowering the TAT further in the semiconductor device production.

### SUMMARY OF INVENTION

An object of the present invention is therefore to provide a method of producing a semiconductor device in which the TAT can be improved while the withstand voltage of a damaged insulating film is secured.

In order to achieve the object, a method of producing a semiconductor device according to the present invention is characterized in that an upper layer of an insulating film is dry etched in a state where at least a part of the insulating film formed on a substrate is exposed, and then, the surface of the insulating film is exposed to a film formation atmosphere of the insulating film.

According to such a production method, the damage given to the surface of the insulating film by the exposure to the dry etching atmosphere is restored by the exposure to the film formation atmosphere of the insulating film. Specifically, a film forming gas of the insulating film enters pin holes produced at the surface side of the insulating film by the exposure to the dry etching atmosphere, and the pin holes are filled with this, so that the film quality (for example, insulation property) of the insulating film is restored to a level equivalent to that before the dry etching. Thus, the insulation property of the insulating film exposed to the dry etching atmosphere can be restored on the insulating film without forming a new insulating film having a film thickness.

### BRIEF DESCRIPTION OF THE DRAWINGS

FIGS. 1A to 1C are sectional process views (No. 1) showing a method of producing a semiconductor device according to an embodiment;

FIGS. 2A and 2B are sectional process views (No. 2) showing the method of producing the semiconductor device according to the embodiment;

FIGS. 3A and 3B are essential part enlargement sectional views for explaining the embodiment in detail; and

FIGS. 4A to 4D are sectional process views showing a conventional production method.

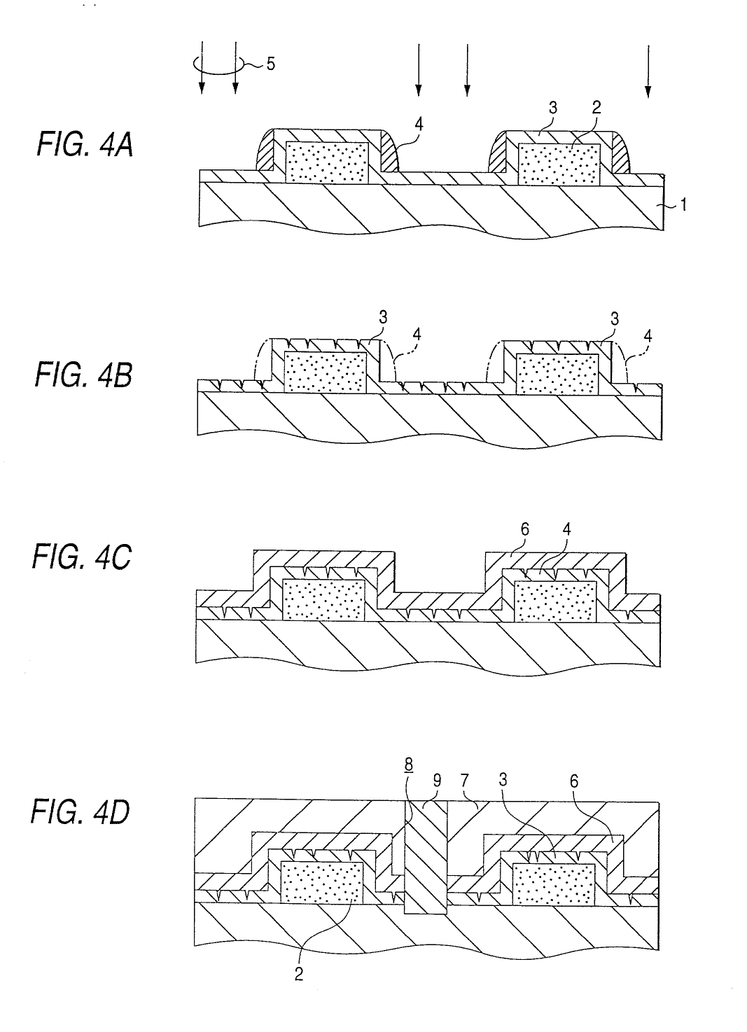

### DETAILED DESCRIPTION OF THE PREFERRED EMBODIMENTS

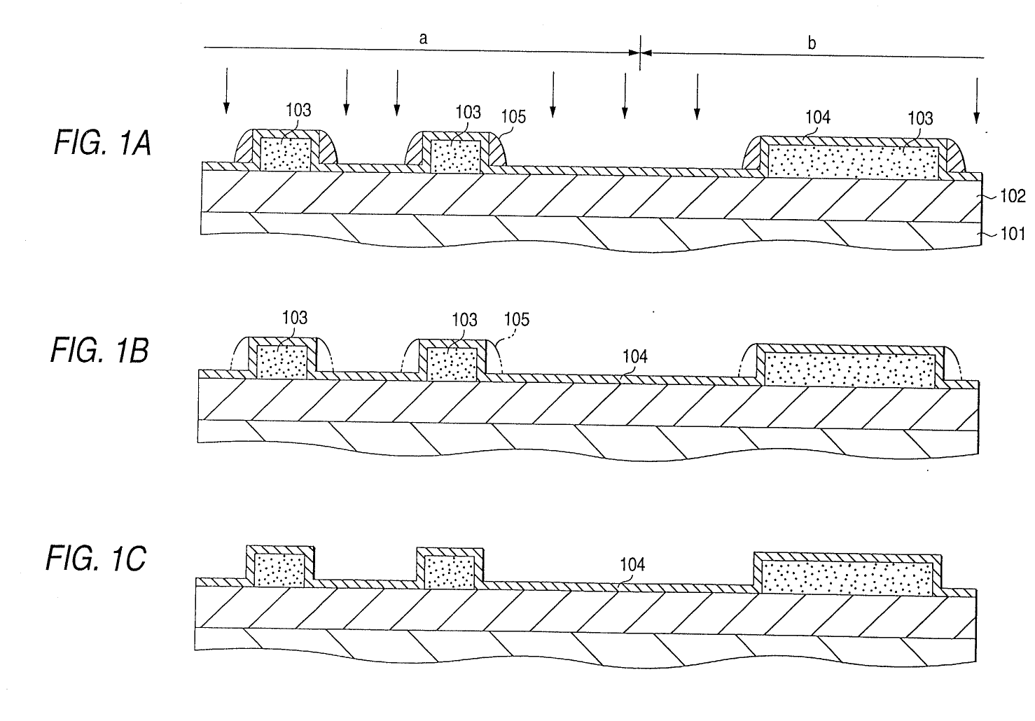

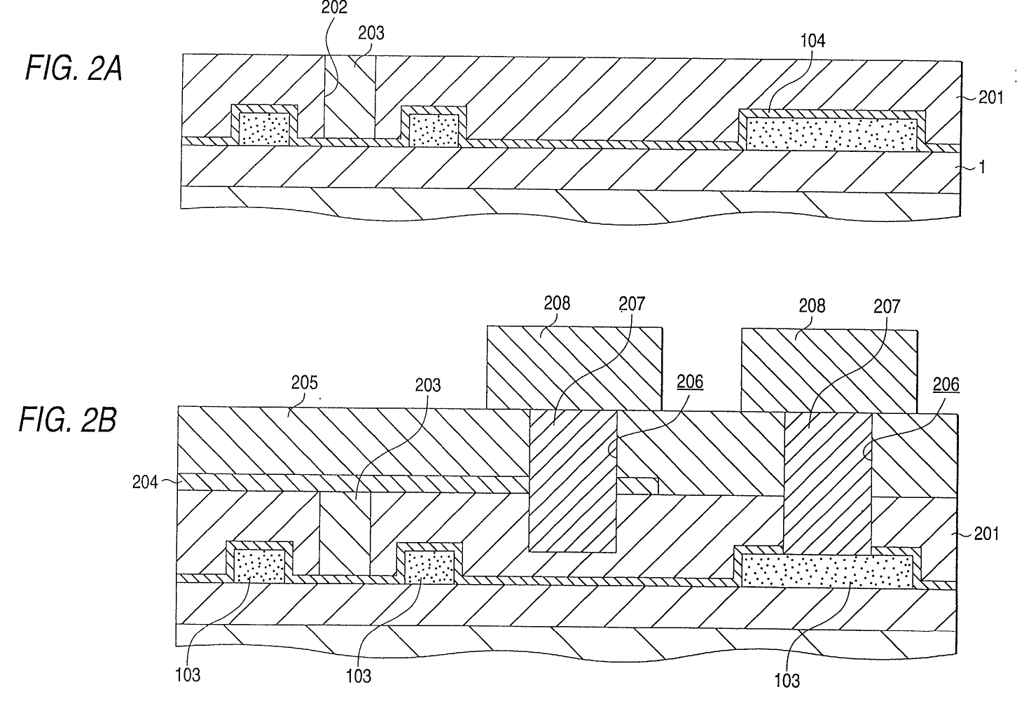

Hereinafter, embodiments of the present invention will be described in detail with reference to the drawings. Here, an embodiment in which a method of producing a semiconductor device according to the present invention is applied to a logic in DRAM process in which a DRAM and a logic are formed on the same substrate, will be described with reference to the sectional process views of FIGS. 1A to 1C and FIGS. 2A and 2B.

First, as shown in FIG. 1A, a substrate 101 made of silicon is prepared, and an element separation 102 made of silicon oxide having a thickness of 270 nm is formed on a surface layer of a DRAM formation region “a” and a logic formation region “b” of this substrate 101.

Next, a film of amorphous silicon (phosphorus-doped amorphous silicon: hereinafter referred to as PDAS) having a thickness of 100 nm, a film of tungsten silicide having a thickness of 100 nm, and a film of silicon nitride oxide having a thickness of 30 nm are successively formed over the substrate 101 on which the element separation 102 is formed. Next, after an annealing treatment is carried out at 800° C. for 10 minutes, these material films are pattern etched, so that gate wiring lines 103 of polycide structure are formed on the substrate 101. The gate wiring line 103 is also used as a word line in the DRAM formation region “a”. Besides, the state is obtained in which the upper surface of the gate wiring line 103 is provided with the silicon nitride oxide film.

Next, a TEOS film 104, that is, a silicon oxide film obtained by a CVD (chemical vapor deposition) method using a TEOS (tetraethoxy silane) gas is formed to a thickness of 30 nm in a state where it covers the gate wiring lines 103. Film formation conditions at this time are set such that for example, the flow of film formation gas is TEOS: N₂=130 cm³/minute: 50 cm³/minute, the temperature of film formation is 700° C., the gas pressure in film formation atmosphere is 50 Pa, and the time of film formation is 15 minutes. Incidentally, in this embodiment, the TEOS film 104 is an insulating film recited in the claims.

Thereafter, a thermal oxidation method is carried out at 850° C. for 28 minutes so that a silicon oxide film having a thickness of 7 nm is formed (not shown) on the exposed surface of the substrate 101. By this, channeling is prevented in the subsequently performed ion implantation for formation of diffusion layers, and a gate bird's beak is formed between the gate wiring line 103 and the substrate 101 to improve the yield of gate withstand voltage.

Therefore, a film of PDAS having a thickness of 140 nm is formed on the TEOS film 104, and next, the PDAS film is etch backed so that the PDAS film remains only at the wall of the gate wiring line 103. By this, a side wall 105 made of PDAS is formed on the wall of the gate wiring line 103 through the TEOS film 104. Then, after a mask pattern is formed on a necessary region, ion implantation for formation of source/drain (not shown) is carried out from above the mask pattern and the sidewall 105. Incidentally, in this embodiment, the side wall 105 is an upper layer pattern recited in the claims.

Next, as shown in FIG. 1B, the side wall 105 is dry etched, and the side wall 105 is removed from the TEOS film 104. In this dry etching, oxygen (O₂)/methane tetrafluoride (CF₄) is used as an etching gas. At this time, the gas flow is set to O₂:CF₄=60 cm³/minutes: 150 cm³/minutes, the gas pressure in etching atmosphere is set to 40 Pa, the applied voltage is set to 700 W, and chemical dry etching for 29 seconds is carried out, so that the side wall 105 on the TEOS film 104 is completely removed.

Next, as shown in FIG. 1C, the surface of the TEOS film 104 is exposed to the same film formation atmosphere as the case where the foregoing TEOS film 104 is formed. However, at this time, it is not necessary to newly form a TEOS film on the TEOS film 104. The surface is exposed to the film formation atmosphere of the TEOS film for a time (for example, about 10 seconds to several tens seconds) to such a degree that the damage given to the TEOS film 104 in the etching step of FIG. 1B is restored, and the treatment is ended when a new film starts to adhere to the surface of the TEOS film 104. Thus, even if the TEOS film is newly formed in this step, the thickness is made less than 10 nm, for example, several nm.

Thereafter, as shown in FIG. 2A, in a state where the roughness on the substrate 1 is filled, ozone (O₃) is used as a film formation gas, and an NSG (non-doped silicate glass) film having a thickness of 550 nm and a BPSG (boro phospho silicate glass) film having a thickness of 350 nm are sequentially laminated to form an interlayer insulating film 201.

Next, the interlayer insulating film 201 is fully etch backed by etching using methane tetrafluoride (CF₄)/argon (Ar) as an etching gas, and the surface is flattened. At this time, the etching is carried out while the gas flow is kept CF₄:Ar=40 cm³/minutes: 800 cm³/minutes, and the gas pressure in etching atmosphere is kept 240 Pa.

Next, a resist pattern (not shown) is formed on the interlayer insulating film 201, and a groove-like connection hole 202 connected to source/drain regions (not shown) of the DRAM region is formed in the interlayer insulating film 201 and the TEOS film 104 by etching from above the resist pattern. Next, after a PDAS film is formed on the interlayer insulating film 201 in a state where it is embedded in the connection hole 202, the PDAS film is etch backed, and further, CMP (Chemical Mechanical Polishing) is carried out, so that a bit contact 203 formed by embedding the PDAS in the connection hole 202 is formed.

Next, as shown in FIG. 2B, a wiring line 204 made of a PDAS film having a thickness of 100 nm is formed on the interlayer insulating film 201 in such a state that it is connected to the bit contact 203. Next, after a BPSG film 205 having a thickness of 350 nm is formed on the interlayer insulating film 201 to cover the wiring line 204 by film formation using ozone (O₃), a reflow treatment is carried out at 850° C. for 10 minutes.

Next, connection holes 206 reaching the wiring line 204 and the gate wiring line 103 of the logic formation region are formed in the BPSG film 205 and the interlayer insulating film 201. Then, a tungsten film is formed through a contact layer in such a state that it is embedded in the connection holes 206. The contact layer is made of titanium (Ti)/titanium nitride (TiN)/Ti=5 nm/50 nm/30 nm successively from an above layer, and after the contact layer is formed, RTA (Rapid Thermal Annealing) (650° C., 30 seconds) is carried out, and next, the tungsten film is formed to a thickness of 600 nm. Thereafter, the tungsten film and the contact layer on the BPSG film 205 are removed by etch backing, and plugs 207 connected to the wiring line 204 and the gate wiring line 103 are formed.

Next, after metal wiring lines 208 connected to the plugs 207 are formed on the BPSG film 205, a sinter treatment (heat treatment) is carried out at 400° C. for 60 minutes. The metal wiring lines 208 are formed by pattern etching of material films laminated in the sequence of, for example, TEOS/Ti/TiN/Ti/AlCu/Ti/TiN/Ti=50/5/100/5/250/5/20/20 nm from an upper layer.

Thereafter, although not shown here, a plasma TEOS film having a thickness of 500 nm is formed as an overcoat layer, and a window is formed in a necessary portion, so that the semiconductor device is completed.

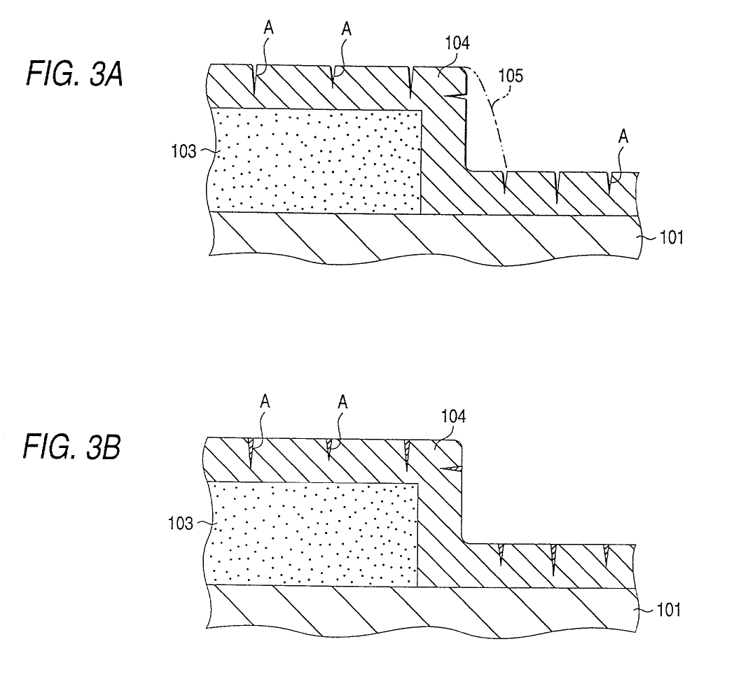

In the method of producing the semiconductor device as described above, when the side wall 105 on the TEOS film 104 is removed in the step of FIG. 1B, the surface of the TEOS film 104 is exposed to the dry etching atmosphere for removing the side wall 105 for a long time. Thus, the TEOS film 104 is damaged by this dry etching. As shown in an enlarged sectional view of FIG. 3A, numerous pin holes A are produced at the surface side of the TEOS film 104 and the film becomes brittle.

Then, in the step of FIG. 1C subsequent to this dry etching step, the surface of the TEOS film 104 is exposed to the same film formation atmosphere as the case where the TEOS film 104 is formed. By this, as shown in FIG. 3B, the film formation gas of the TEOS film enters the pin holes A of the TEOS film 104, and the pin holes A are filled by this. As a result, the damage (pin holes) of the TEOS film 104 caused by the exposure to the dry etching is restored, and the film quality of the TEOS film 104 is restored to a level equivalent to that before the dry etching.

It is not necessary to form a new TEOS film having a thickness on the TEOS film 104, and the surface of the TEOS film 104 has only to be exposed to the film formation atmosphere for a short time of about 10 seconds to several tens seconds. Accordingly, as compared with the case where the TEOS film 104 is reinforced by forming a new film, a treatment time can be greatly shortened. As a result, it becomes possible to shorten the TAT of the semiconductor device production.

In the production process described above, a semiconductor device was produced while the formation position of the bit contact 203 was made a parameter, and the withstand voltage between the bit contact 203 and the word line 103 was measured. As a result, even when the interval between the bit contact 203 and the word line 103 was 20 nm which was shorter than the thickness (30 nm) of the initial TEOS film 104, satisfactory withstand voltage was obtained, and it was confirmed that the film quality of the TEOS film 104 was restored.

Incidentally, in the above embodiment, the case where the damage of the TEOS film 104 is restored has been exemplified. However, the present invention is not limited to the TEOS film, but as long as an insulating film is formed by a CVD method, the same effect can be obtained by exposing it to the film formation atmosphere of the insulating film.

As described above, according to the method of producing the semiconductor device of the present invention, the surface of the insulating film is exposed to the film formation atmosphere of the insulating film, so that the damage of the surface of the insulating film can be restored. Accordingly, it becomes possible to restore the film quality of the insulating film and to secure the withstand voltage without forming a new insulating film having a thickness on the insulating film, and the TAT in the semiconductor device production can be improved.

We claim:

1. A method of producing a semiconductor device, comprising the steps of:
dry etching an upper layer pattern of an insulating film in a state where at least a part of the insulating film formed on a substrate is exposed; and
exposing a surface of the insulating film to a film formation atmosphere of the insulating film.

2. A method of producing a semiconductor device according to claim 1, wherein the insulating film is formed by a chemical vapor deposition method.
